(19) United States
(12) Patent Application Publication
(10) Pub. No.: US 2017/0025624 A1
(43) Pub. Date: Jan. 26, 2017

(54) Metal Complex and Organic Light-Emitting Component

(71) Applicant: OSRAM GmbH, Muenchen (DE)

(72) Inventors: Jude Eko Namanga, Augsburg (DE); Niels Gerlitzki, Augsburg (DE)

(21) Appl. No.: 15/215,381

(22) Filed: Jul. 20, 2016

(30) Foreign Application Priority Data
Jul. 24, 2015 (DE) 10 2015 112 132.8

(51) Int. Cl. H01L 51/00; C09K 11/02; C07F 15/00; C09K 11/06

(52) U.S. Cl. CPC H01L 51/0085; C09K 11/06; C09K 11/025; H01L 51/0061; H01L 51/0072; C07F 15/0033; H01L 51/5032

(57) ABSTRACT

A metal complex and an organic light-emitting component are disclosed. In an embodiment the metal complex includes the following structural formula I:

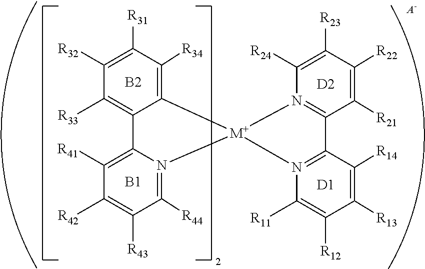

This patent application claims the priority of German patent application 10 2015 112 132.8, filed Jul. 24, 2015, which is incorporated herein by reference in its entirety.

### TECHNICAL FIELD

The invention relates to a metal complex. The invention further relates to an organic light-emitting component.

### BACKGROUND

Organic light-emitting components, especially organic light-emitting electrochemical cells (OLECs or LECs), include metal complexes, especially ionic transition metal complexes (iTMCs), as emitter materials, which can emit preferentially in the blue, sky blue, green, yellow-green, yellow, orange or red spectral region. However, these emitter materials are of low structural stability during the operation of the organic light-emitting component, and so the organic light-emitting component has a short lifetime.

### SUMMARY OF THE INVENTION

Embodiments of the invention provide a structurally stable metal complex. More particularly, the metal complex is stable to degradation and/or at high temperatures and/or over a long period. Further embodiments of the invention to provide a stable organic light-emitting component. More particularly, the component has a long lifetime with equal or high luminescence compared to components known to date that comprise conventional metal complexes.

In at least one embodiment, the metal complex has the structural formula I:

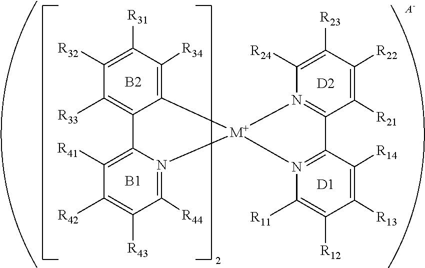

where:

M is a transition metal having an atomic number greater than 40,

the B2 ring is at least one aromatic or heteroaromatic,

the B1 ring, the D1 ring and the D2 ring are each at least one nitrogen-containing ring,

A⁻ is a monovalent anion,

R₁₁, R₁₂, R₁₃, R₁₄, R₂₁, R₂₂, R₂₃, R₂₄, R₃₁, R₃₂, R₃₃, R₃₄, R₄₁, R₄₂, R₄₃, R₄₄, are either each independently selected from a group comprising —H, —OH, —R₅₀, -phenyl, —OCOR₆₀, —NHCOR₇₀, —OR₈₀, —NR₉₀R₁₀₀, —NHR₁₁₀, —C═, —C═C, —C═C—, —C and —NH₂ or each independently selected from a group comprising —H, —I, —Cl, —Br, —F, N⁺R₁₂₀R₁₃₀R₁₄₀, —SO₃R₁₅₀, —CN, —COCl, —NO₂, —COOR₁₆₀, —CR₁₇₀R₁₈₀OH, —CR₁₉₀O and —CHO,

where R₅₀, R₆₀, R₇₀, R₈₀, R₉₀, R_{100,} R₁₁₀ are each independently selected from a group comprising unbranched saturated hydrocarbon chains having one to 20 carbon atoms, branched saturated hydrocarbon chains having one to 20 carbon atoms, unbranched unsaturated hydrocarbon chains having one to 20 carbon atoms, branched unsaturated hydrocarbon chains having one to 20 carbon atoms, aromatic rings and nonaromatic rings,

where R₁₂₀, R₁₃₀, R₁₄₀, R₁₅₀, R₆₀, R₁₇₀, R₁₈₀, R₁₉₀ are each independently selected from a group comprising unbranched saturated hydrocarbon chains having one to 20 carbon atoms, branched saturated hydrocarbon chains having one to 20 carbon atoms and cyclic rings having 3 to 20 carbon atoms,

where at least one of the R₃₁, R₃₂, R₃₃ and R₃₄ radicals is an electron-withdrawing substituent.

“Metal complex” or metal complex compound here and hereinafter is understood to mean a chemical compound having a central atom of a transition metal M which has gaps in its electron configuration and is surrounded by at least one or more than one molecule or ion, also called ligands. The central atom may bear a positive charge (M⁺). The ligands each provide at least one free electron pair for the formation of the metal complex. The metal complex especially forms six coordinate bonds to the ligands. The ligands may be monodentate or polydentate, for example bidentate. More particularly, bonds are formed from the central atom M to the B1, B2, D1 and D2 rings. Since the B1 and B2 rings are present twice in the metal complex, represented by the index 2 in the structural formula I, the result is six bonds from the respective rings to the central atom M. More particularly, the B1, D1 and D2 rings each coordinate via the nitrogen of the corresponding ring to M. More particularly, the respective B2 ring coordinates via a carbon in the B2 ring to M.

In at least one embodiment, M is a transition metal having an atomic number greater than 40. Atomic number refers to the number of protons in the atomic nucleus of the chemical transition metal. More particularly, M is a transition metal selected from groups 8 to 10 of the Periodic Table. In various embodiments, M is selected from a group comprising iridium (Ir), ruthenium (Ru), osmium (Os), platinum (Pt), palladium (Pd) and rhodium (Rh). In a particular embodiment, M is iridium.

In at least one embodiment, the B2 ring is at least one aromatic or heteroaromatic. The B2 ring may be selected from a group comprising at least one fused aromatic, for example naphthalene, an unfused aromatic, for example benzene, a fused heteroaromatic, for example phenanthroline, and an unfused heteroaromatic, for example pyridine. The aromatic and/or heteroaromatic may be substituted or unsubstituted. “Unsubstituted” in respect of the B2 ring here means that three of the four R₃₁, R₃₂, R₃₃, R₃₄ radicals are each hydrogen and at least one of the R₃₁, R₃₂, R₃₃ and R₃₄ radicals is an electron-withdrawing substituent. “Substituted” here and hereinafter means that the R₃₁, R₃₂, R₃₃ or R₃₄ radicals having no electron-withdrawing substituents have substituents other than hydrogen.

Alternatively or additionally, the aromatics or heteroaromatics of the B2 ring may additionally be fused to further aromatic or nonaromatic rings. This is the case especially when adjacent radicals in the B2 ring include the —C═C—, —C═C, —C, N═C—, —N—C units and are joined to one another indirectly or directly. More particularly, the result in that case is a fused ring structure comprising at least one B2 ring having a carbon. In embodiments, the fused ring structure in that case is coordinated to transition metal M via a sp²-hybridized carbon atom.

The R₁₁, R₁₂, R₁₃, R₁₄, R₂₁, R₂₂, R₂₃, R₂₄, R₃₁, R₃₂, R₃₃, R₃₄, R₄₁, R₄₂, R₄₃, R₄₄ radicals may each independently be selected from a group comprising —H, —OH, —R₅₀, -phenyl, —OCOR₆₀, —NHCOR₇₀, —OR₈₀, —NR₉₀R₁₀₀, —NHR₁₁₀, —C═,—C═C, —C═C—, —C and —NH₂. Alternatively, these radicals may each independently be selected from a group comprising —H, —I, —Cl, —Br, —F, N⁺R₁₂₀R₁₃₀R₁₄₀, —SO₃R₁₅₀, —CN, —COCl, —NO₂, —COOR₁₆₀, —CR₁₇₀R₁₈₀OH, —CR₁₉₀O and —CHO.

R₅₀, R₆₀, R₇₀, R₈₀, R₉₀, R₁₀₀, R₁₁₀ here are each independently selected from a group comprising unbranched saturated hydrocarbon chains having one to 20 carbon atoms, for example ethyl, branched saturated hydrocarbon chains having one to 20 carbon atoms, for example tert-butyl, unbranched unsaturated hydrocarbon chains having one to 20 carbon atoms, for example vinyl, branched unsaturated hydrocarbon chains having one to 20 carbon atoms, for example 4-methyl-1-hepten-5-ynyl, aromatic rings, for example benzyl, and nonaromatic rings, for example cyclopentyl.

R₁₂₀, R₁₃₀, R₁₄₀, R₁₅₀, R₁₆₀, R₁₇₀, R₁₈₀, R₁₉₀ here are each independently selected from a group comprising unbranched saturated hydrocarbon chains having one to 20 carbon atoms, branched saturated hydrocarbon chains having one to 20 carbon atoms and cyclic rings having 3 to 20 carbon atoms.

The terms “substituent” and “radical” are used synonymously here and hereinafter.

In at least one embodiment, at least one of the R₃₁, R₃₂, R₃₃ and R₃₄ radicals is an electron-withdrawing substituent selected from a group comprising —I, —Cl, —Br, —F, —NO₂, N⁺R₁₂₀ R₁₃₀R₁₄₀, —SO₃R₁₅₀, —CN, —COCl, —COOR₁₆₀, —C═, —C═C, —C═C—, —C, —CR₁₇₀R₁₈₀OH, —CR₁₉₀O and —CHO. R₅₀, R₆₀, R₇₀, R₈₀, R₉₀, R₁₀₀, R₁₁₀ may have the same meaning as described above. More particularly, the electron-withdrawing substituent is selected from a group comprising —I, —Cl, —Br, —F, —CN and —NO₂. In a particular embodiment, the electron-withdrawing substituent is —F.

“Electron-withdrawing substituents” refers here and hereinafter to functional groups that can exert a —I effect, i.e. a negative inductive effect, via a sigma bond. More particularly, electron-withdrawing substituents may be halogens, for example fluorine (—F), chlorine (—Cl), bromine (—Br) or iodine (—I). Alternatively, the functional group may exert a -M effect, i.e. a negative mesomeric effect, via a a bond, for example via a nitro group (—NO₂). The electron-withdrawing substituent may, for example, also be a CN group.

In at least one embodiment, the R₃₁ and/or R₃₄ substituent is/are each a fluorine. In other words, the B2 ring has, in position 3 and/or 4 according to the structural formula III (see below), a fluorine as substituent. In this way, it is possible to increase the stability of the metal complex.

In at least one embodiment, the B1 ring is at least one nitrogen-containing ring. The B1 ring may be selected from a group comprising at least one fused heteroaromatic, for example quinoline, phenanthrene or isoquinoline, and an unfused heteroaromatic, for example pyridine or pyrimidine. The B1 ring may be substituted or unsubstituted. “Unsubstituted” for the B1 ring here means that all four R₄₁, R₄₂, R₄₃, R₄₄ radicals are hydrogen. “Substituted” here and hereinafter means that the rings have substituents other than hydrogen.

Alternatively or additionally, the B1 ring may additionally be fused to further aromatic or nonaromatic rings. More particularly, this is the case when adjacent radicals of the B1 ring have the —C═C—, —C═C, —C, N═C—, —N—C units and are joined indirectly or directly to one another. More particularly, the result in that case is a fused ring structure comprising at least one B1 ring having a nitrogen. In that case, the fused ring structure is preferably coordinated to the transition metal M via an sp²-hybridized nitrogen atom.

In at least one embodiment, the B1 ring is a nitrogen-containing ring. In various embodiments, the B1 ring is a pyridine substituted on the B2 ring. More particularly, the nitrogen of the pyridine is sp²-hybridized and coordinates to the transition metal M.

The nitrogen-containing ring may additionally be fused to further aromatic or nonaromatic rings. It is possible for a fused ring structure to be formed, comprising the B1 and B2 rings.

In at least one embodiment, the B1 ring is a substituted or unsubstituted quinoline or isoquinoline.

More particularly, the R₄₁ and R₄₂ substituents of the B1 ring may be fused to form an aromatic. This forms isoquinoline comprising the B1ring.

Alternatively, the R₄₄ and R₄₃ radicals of the B1 ring may be fused to form an aromatic. This forms quinoline comprising the B1 ring.

In at least one embodiment, the metal complex has a D1 ring. The D1 ring is at least one nitrogen-containing ring. Alternatively, it is also possible for more than one nitrogen to be part of the D1 ring. The D1 ring may additionally be fused to aromatic or nonaromatic rings. The D1 ring may be substituted or unsubstituted.

In at least one embodiment, the metal complex has a D2 ring. The D2 ring is at least one nitrogen-containing ring. One nitrogen coordinates to the transition metal in particular and hence forms a coordinate bond. The D2 ring may additionally be fused to aromatic or nonaromatic rings.

The D1 ring may form a fused structure, for example with the D2 ring. In this case, both the D1 ring and the D2 ring are part of a fused ring system. This fused ring system may be joined to the transition metal via at least one nitrogen atom. More particularly, both the D1 ring and the D2 ring coordinate to the transition metal M via their nitrogen atoms. In this case, both nitrogen atoms have sp² hybridization.

In various embodiments, the D1 and/or D2 ring in each case is a quinoline coordinated to the transition metal via the nitrogen of the quinoline.

The D2 ring may be substituted or unsubstituted.

In at least one embodiment, the D1 ring and/or the D2 ring is a quinoline or isoquinoline.

In other words, both the D1 ring and the D2 ring may be part of a quinoline or isoquinoline. For example, the D1 ring may have, via the R₁₁ and R₁₂ radicals, a further aromatic system coordinated to the D1 ring. In this case, the D1 ring forms a quinoline with the further aromatic system. Alternatively, a further aromatic system may be coordinated to the D1 ring via the R₁₂ and R₁₃ radicals. The D1 ring is thus part of an isoquinoline. This applies correspondingly to the D2 ring. In this case, a further aromatic system fused to the D2 ring forms a quinoline via the R₂₄ and R₂₃ radicals. A further aromatic system fused to the D2 ring forms an isoquinoline via the R₂₃ and R₂₂ radicals.

The quinoline formation of the D1 and D2 rings is also shown in the structural formula II (see below).

The metal complex of the following structural formula III especially shows the nomenclature used according to the application for the positions of the individual atoms in the corresponding B1, B2, D1and/or D2 rings:

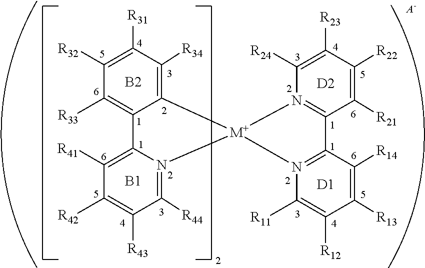

More particularly, the B1, B2, D1, D2 rings form a coordinate bond to the transition metal complex M at their respective 2 positions. More particularly, the B1 and B2 rings are joined to one another at least via their respective 1 positions. Correspondingly, the D1 and D2 rings are joined to one another via their respective 1 positions. The electron-withdrawing substituent is especially disposed in each case at positions 3 and/or 4 of the B2 ring. Alternatively, further electron-withdrawing substituents, preferably fluorine, may be attached at positions 5 and/or 6 of the B1 ring.

The metal complex of the structural formula IV is shown below.

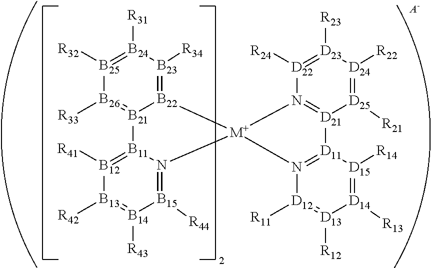

The structural formula IV shows that the atoms of the B1, B2, D1 and/or D2 rings need not necessarily have carbon atoms where they had carbon atoms according to structural formula I. For example, B₁₁, B₁₂, B₁₃, B₁₄, B₁₅, B₂₁, B₂₂, B₂₃, B₂₄, B₂₅, B₂₆, D₁₁, D₁₂, D₁₃, D₁₄, D₁₅, D₂₁, D₂₂, D₂₃, D₂₄, D₂₅ may be independently selected from nitrogen and carbon. More particularly, the B2 ring, as shown in the structural formula I, need not necessarily have carbon atoms at positions 1 to 6. Optionally, the B2 ring may also have nitrogen atoms at positions 1, 3, 4, 5 and/or 6. More particularly, B22 is a carbon, in order not to alter the charge of M, since the ligands that are formed by the B1 and B2 rings are anionic ligands.

In at least one embodiment, A⁻ is a monovalent anion. In other words, A⁻ in particular is a singly negatively charged atom or molecule. More particularly, the monovalent anion is selected from a group including the following negatively charged elements or compounds: fluorine (F⁻), chlorine (Cl⁻), bromine (Br⁻), iodine (I⁻), NO₃⁻, NO₂⁻, BF₄⁻, PF₆⁻, CF₃SO₃⁻, CH₃SO₃⁻, Tf₂N⁻ (trifluoromethylsulfonimide). In a particular embodiment, A⁻ is a tetrafluorobromide (BF₄⁻) or hexafluorophosphate (PF₆⁻).

In at least one embodiment, the metal complex is ionic. What this means is that the central atom and the B1, B2, D1 and D2 rings form a positively charged molecule, i.e. a cation. Thus, it has a positive net charge. This positive net charge can be compensated for by a counterion, especially by the monovalent anion.

In at least one embodiment, the metal complex is set up to emit radiation from the red or red to deep red spectral region. The red spectral region refers here and hereinafter to a wavelength range from 600 to 635 nm, for example 632 nm. The deep red spectral region refers here and hereinafter to a wavelength range from 636 nm to 685 nm, for example 656 nm.

In at least one embodiment, the metal complex has an emission maximum at a wavelength of 636+/−8 nm. More particularly, the excitation of the metal complex is effected in the UV spectral range, especially between 340 and 380 nm, for example at 350 nm.

In at least one embodiment, the metal complex has the following structural formula II:

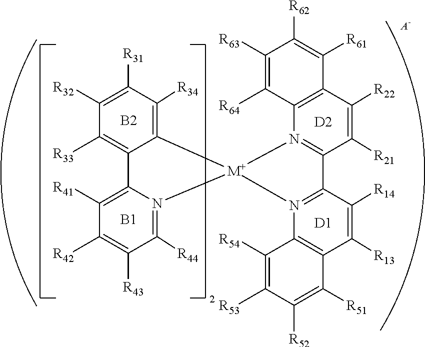

where:

R₃₁ and/or R₃₄ is/are each independently selected from —F, —I, —Br, —Cl, —CN and —NO₂,

R₅₁, R₅₂, R₅₃, R₅₄, R₆₁, R₆₂, R₆₃, R₆₄ are each hydrogen, and

M, the B2 ring, the B1 ring, the D1 ring and/or the D2 ring, A⁻, R₄₁, R₄₂, R₄₃, R₄₄, R₃₁, R₃₂, R₃₃, R₃₄, R₁₃, R₁₄, R₂₁, R₂₂ are as defined in the structural formula I.

Alternatively, R₅₁, R₅₂, R₅₃, R₅₄, R₆₁, R₆₂, R₆₃, R₆₄ may be radicals other than hydrogen, for example analogously to the radicals of R₂₃ or R₁₃.

In this context, all the definitions and embodiments cited above for the metal complex of the structural formulae I, III and IV also apply to the metal complex of the structural formula II, and vice versa.

In at least one embodiment, the metal complex of the structural formula II has a fluorine in each case as the R₃₁ and/or R₃₄ radical. Alternatively, another halogen, such as —Cl, —I or —Br, or else —CN or —NO₂ can be used in place of fluorine.

In at least one embodiment, the B2 ring is a fluorine-substituted phenyl radical.

In at least one embodiment, the B1 ring of the metal complex of the structural formula II is part of a quinolone or isoquinoline. More particularly, the quinolone or isoquinoline is substituted or unsubstituted. Possible substituents include, for example, the same radicals as for R₂₃ or R₁₃.

In at least one embodiment, the B1 and B2 rings of the metal complex of the structural formula II or I form a bidentate ligand. More particularly, this bidentate ligand is a monoanionic ligand coordinated to the transition metal M. More particularly, this bidentate ligand coordinates to the transition metal M via a carbon atom of the B2 ring and via a nitrogen atom of the B1 ring. These ligands are preferably referred to as cyclometallizing ligands. In addition, the D1 and D2 rings form a bidentate ligand which can also be referred to as a bidentate chelate diimide ligand. This bidentate ligand comprises at least the D1 ring and also the D2 ring. More particularly, this bidentate ligand coordinates to the transition metal M via at least one nitrogen atom of the D1 ring and via a nitrogen atom of the D2 ring.

In at least one embodiment, the metal complex has the structural formula II. More particularly, the R₃₁ radical is an electron-withdrawing substituent, especially fluorine. The other radicals of the B2, B1, D2 and D1 ring may each be hydrogen. The result is a metal complex of the structural formula V which shows, by way of example, iridium as transition metal M and [PF₆]⁻ as monovalent anion A⁻.

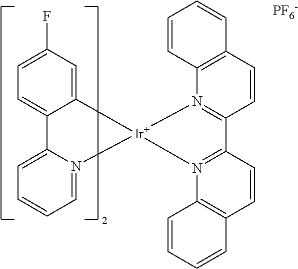

PF₆⁻ and Ir in the structural formula V here are merely examples and may also be replaced by other transition metals M or monovalent anions A⁻. Instead of F, it is also possible to use another electron-withdrawing substituent.

The metal complex of the structural formula V may be referred to as [iridium(2-(4-fluorophenyl)pyridinato)2(2,2′-biquinoline)]PF₆.

In at least one embodiment, the metal complex has the structural formula II. More particularly, the R₃₄ radical is an electron-withdrawing substituent, especially fluorine. The other radicals of the B2, B1, D2 and D1 ring may each be hydrogen. The result is a structural formula VI which shows, by way of example, iridium as transition metal M and [PF₆]⁻ as monovalent anion A⁻.

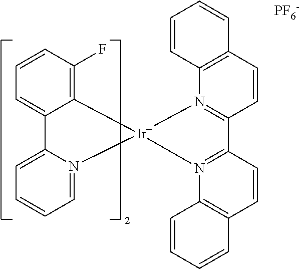

PF₆⁻ and Ir in the structural formula VI here are merely examples and may also be replaced by other transition metals M or monovalent anions A⁻. Instead of F, it is also possible to use another electron-withdrawing substituent.

The metal complex of the structural formula VI may be referred to as [iridium(2-(3-fluorophenyl)pyridinato)2(2,2′-biquinoline)]PF₆.

In at least one embodiment, the metal complex has the structural formula II. More particularly, the R₃₁ radical is an electron-withdrawing substituent, especially fluorine. The B1 ring forms a quinoline. The other radicals of the B2, B1, D2 and D1 rings may each be hydrogen. The result is a structural formula VII which shows, by way of example, iridium as transition metal M and [PF₆]⁻ as monovalent anion A⁻.

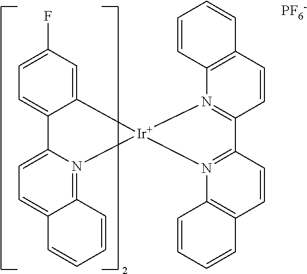

PF₆⁻ and Ir in the structural formula VII here are merely examples and may also be replaced by other transition metals M or monovalent anions A⁻. Instead of F, it is also possible to use another electron-withdrawing substituent.

The metal complex of the structural formula VII may be referred to as [iridium(2-(4-fluorophenyl)quinolinato)2(2,2′-biquinoline)]PF₆.

In at least one embodiment, the metal complex has the structural formula II. More particularly, the R₃₁ radical is an electron-withdrawing substituent, especially fluorine. The B1 ring forms an isoquinoline. The other radicals of the B2, B1, D2 and D1 rings may each be hydrogen. The result is a structural formula VIII which shows, by way of example, iridium as transition metal M and [PF₆]⁻ as monovalent anion A⁻.

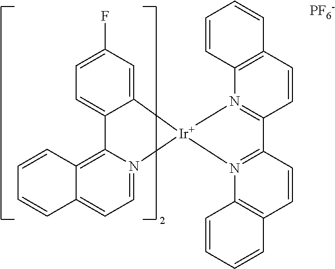

PF₆⁻ and Ir in the structural formula VIII here are merely examples and may also be replaced by other transition metals M or monovalent anions A⁻. Instead of F, it is also possible to use another electron-withdrawing substituent.

The metal complex of the structural formula VIII may be referred to as [iridium(1-(4-fluorophenyl)isoquinalinato)2(2,2′-biquinoline)]PF₆.

In at least one embodiment, the metal complex has the structural formula II. More particularly, the R₃₄ radical is an electron-withdrawing substituent, especially fluorine. The B1 ring forms an isoquinoline. The other radicals of the B2, B1, D2 and D1 rings may each be hydrogen. The result is a structural formula IX which shows, by way of example, iridium as transition metal M and [PF₆]⁻ as monovalent anion A⁻.

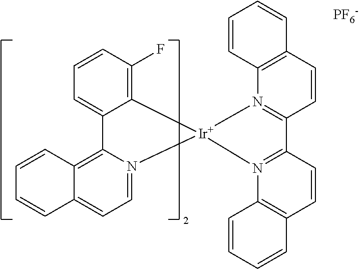

PF₆⁻ and Ir in the structural formula IX here are merely examples and may also be replaced by other transition metals M or monovalent anions A⁻. Instead of F, it is also possible to use another electron-withdrawing substituent.

The metal complex of the structural formula IX may be referred to as [iridium(1-(3-fluorophenyl)isoquinolinato)2(2,2′-biquinoline)]PF₆.

In at least one embodiment, the metal complex has the structural formula II. More particularly, the R₃₄ radical is an electron-withdrawing substituent, especially fluorine. The B1 ring forms a quinolone. The other radicals of the B2, B1, D2 and D1 ring may each be hydrogen. The result is a structural formula X which shows, by way of example, iridium as transition metal M and [PF₆]⁻ as monovalent anion A⁻.

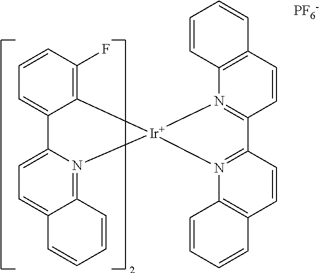

PF₆⁻ and Ir in the structural formula X here are merely examples and may also be replaced by other transition metals M or monovalent anions A⁻. Instead of F, it is also possible to use another electron-withdrawing substituent.

The metal complex of the structural formula X may be referred to as [iridium(2-(3-fluorophenyl)quinolinato)2(2,2′-biquinoline)]PF₆.

The inventors have recognized that the metal complexes of the structural formulae I to X have high structural stability. More particularly, the metal complexes have high stability at high temperatures or during the operation of a light-emitting organic component. Furthermore, the brightness and efficiency of the light-emitting organic component is increased by virtue of the metal complex having at least one electron-withdrawing substituent on the B2 ring.

The invention further relates to a process for preparing a metal complex. In various embodiments, the process prepares the metal complex. Thus, all the definitions and embodiments cited for the metal complex also apply to the process, and vice versa.

The process for preparing a metal complex has the process steps of:

A) providing a transition metal M which is part of a central atom compound, and

B) mixing the central atom compound with ligands dissolved in solvents to form a metal complex, where the ligands comprise the rings B1, B2, D1 and D2, and the rings B1, B2, D1, D2 each form a coordinate bond to the central atom or transition metal.

In at least one embodiment, the metal complex is purified by column chromatography.

For example, a metal complex of the structural formula I can be prepared as disclosed, for example, in J. D. Slinker et al., J. Am. Chem. Soc., 2004, 126, pages 2736-2767, E. Holder et al., 2005, Adv. Mater. 2005, 17, pages 1109-1121 and L. Chun et al., Eur. J. Org. Chem., 2010, 29, pages 5548 to 5551.

Additionally specified is an organic light-emitting component. Preferably, the organic light-emitting component includes the metal complex. This means that all the definitions and embodiments cited for the metal complex also apply to the component, and vice versa.

In at least one embodiment, the organic light-emitting component has at least one organic light-emitting layer between two electrodes. The organic light-emitting layer includes a metal complex, preferably the above-described metal complex, as emitter material.

In at least one embodiment, the organic light-emitting component is an organic light-emitting diode (OLED). Alternatively, the organic light-emitting component may be an organic light-emitting electrochemical cell (OLEEC). The organic light-emitting component has at least one organic light-emitting layer.

An organic light-emitting electrochemical cell generally differs from an organic light-emitting diode in that the electrochemical cell has just one organic light-emitting layer between the two electrodes. In other words, the electrochemical cell does not have any further layers, especially injection layers, transport layers and/or blocker layers. Thus, the organic light-emitting electrochemical cell has a simpler structure compared to an organic light-emitting diode. By contrast, the organic light-emitting diode generally has a functional layer stack.

The functional layer stack may include layers comprising organic polymers, organic oligomers, organic monomers, organic small non-polymeric molecules (“small molecules”) or combinations thereof. The functional layer stack may have, in addition to the at least one organic light-emitting layer, a further functional layer executed in the form of a hole transport layer, in order to enable effective hole injection into at least the organic light-emitting layer. Advantageous materials for a hole transport layer may be found, for example, to be tertiary amines, carbazole derivatives, camphorsulfonic acid-doped polyaniline or polystyrenesulfonic acid-doped polyethylenedioxythiophene. The functional layer stack may further include at least one functional layer which takes the form of an electron transport layer. In general, the functional layer stack may have, in addition to the organic light-emitting layer, further layers selected from hole injection layers, hole transport layers, electron injection layers, electron transport layers, hole blocker layers and electron blocker layers.

In at least one embodiment, the organic light-emitting component has at least two electrodes. More particularly, the functional layer stack is arranged between the two electrodes.

In at least one embodiment, at least one of the electrodes is transparent. “Transparent” refers here and hereinafter to a layer which is transparent in respect of visible light. The transparent layer may be clear and translucent or at least partly light-scattering and/or partly light-absorbing, such that the transparent layer may, for example, also have diffuse or milky translucency. In various embodiments, a layer referred to here as transparent has maximum transparency, such that, more particularly, the absorption of the light or radiation generated in the functional layer stack in the course of operation of the component is as small as possible.

In at least one embodiment, both electrodes are transparent. Thus, the light generated in the organic light-emitting layer can be emitted in both directions, i.e. through both electrodes. In other words, the device is a transparent OLED or OLEEC. Alternatively, the light can also be emitted in just one direction, for example through an electrode facing the substrate. In this case, reference is also made to a bottom emitter. If the light is emitted through the electrode facing away from the substrate, reference is also made to a top emitter.

The material used for a transparent electrode may, for example, be a transparent conductive oxide. Transparent conductive oxides (“TCOs” for short) are generally metal oxides, for example zinc oxide, tin oxide, cadmium oxide, titanium oxide, indium oxide or indium tin oxide (ITO). As well as binary metal-oxygen compounds, for example ZnO, SnO₂ or In₂ O₃, the group of the TCOs also includes ternary metal-oxygen compounds, for example Zn₂SnO₄, CdSnO₃, ZnSnO₃, MgIn₂O₄, GaInO₃, Zn₂In₂O₅ or In₄Sn₃O₁₂, or mixtures of different transparent conductive oxides. At the same time, the TCOs do not necessarily correspond to a stoichiometric composition and may additionally be p- or n-doped. More particularly, the transparent material is indium tin oxide (ITO).

The second electrode, which is especially in non-transparent form, may, for example, be the cathode and may consist of or comprise aluminum, barium, indium, silver, gold, magnesium, calcium or lithium, and combinations or alloys thereof. The material for the second electrode is especially air-stable and/or non-reactive. It is thus possible to dispense with hermetic sealing of the organic light-emitting component. This saves costs and time in the production of the organic light-emitting component.

In at least one embodiment, the organic light-emitting layer is arranged in direct contact with the first electrode and with the second electrode. “Direct contact” is understood here to mean especially direct mechanical and/or electrical contact.

In at least one embodiment, the organic light-emitting component has a substrate. More particularly, one of the two electrodes is disposed on the substrate. The substrate may, for example, include one or more materials in the form of a layer, a sheet, a film or a laminate, these being selected from glass, quartz, plastic, metal, silicon, wafer. More particularly, the substrate includes or consists of glass.

In at least one embodiment, the component is set up, especially set up in operation, to emit radiation from the red or deep red spectral region. In embodiments, the dominant wavelength of the red wavelength range has a value of 620 nm with a tolerance of 20 nm from this value. In further embodiments, the dominant wavelength of the deep red wavelength range has a value of 660 nm with a tolerance of 20 nm from this value. Dominant wavelength refers to the wavelength that describes the hue of an OLED or LEC as perceived by the human eye.

In at least one embodiment, the organic light-emitting component has an encapsulation. In various embodiments the encapsulation is applied in the form of a thin-film encapsulation to the organic light-emitting component. More particularly, the encapsulation protects the functional layer stack or at least the organic light-emitting layer and the electrodes from the environment, for example from moisture and/or oxygen and/or other corrosive substances, for instance hydrogen sulfide. The encapsulation may include one or more thin layers applied, for example, by means of chemical vapor deposition (CVD). For example, the encapsulation may be a glass lid that has been stuck on.

The inventors have recognized that the metal complex of at least the structural formula I can provide an efficient and stable emitter material for an organic light-emitting component. More particularly, the organic light-emitting component may have a flexible size. The organic light-emitting component can be employed in packaging or lighting.

In at least one embodiment, the organic light-emitting layer may have been produced from the liquid phase. More particularly, the treatment can be effected by a solution-based process, such as a roll-to-roll process, spin-coating or printing method. It is thus possible to prepare the metal complex inexpensively compared to the vapor-deposited metal complexes.

In at least one embodiment, the organic light-emitting layer has been produced from the liquid phase, and the metal complex is homogeneously distributed in a matrix material. Alternatively, the metal complex may also have a concentration gradient in the matrix material. The matrix material may, for example, be TCTA, tris(4-carbazol-9-yl)triphenylamine, or CBP, 4,4′-bis(N-carbazolyl)-1,1′-biphenyl.

In at least one embodiment, the matrix material includes further additional materials which may be uncharged or have an ionic charge. For example, the further material may be an ionic liquid. Ionic liquids used may, for example, be 1-butyl-3-methylimidazolium hexafluorophosphate.

In at least one embodiment, the metal complex is distributed within the matrix material at least to an extent of 60% by weight, especially to an extent of 80% by weight, preferably more than 90% by weight.

### BRIEF DESCRIPTION OF THE DRAWINGS

Further advantages, advantageous embodiments and developments will be apparent from the working examples described hereinafter in conjunction with the figures.

The figures show:

FIG. 1 a schematic side view of an organic light-emitting component in one embodiment;

FIG. 2 a schematic side view of an organic light-emitting component in one embodiment;

Each of FIGS. 3A to 4B an emission spectrum of one embodiment;

FIGS. 5A to 6C the luminescence or efficiency as a function of time in one embodiment; and

FIGS. 7A and 7B experimental data in one embodiment.

In the working examples and figures, elements that are identical or of the same type or have the same effect may each be given the same reference signs. The elements shown and their size ratios relative to one another should not be regarded as being to scale. Instead, individual elements, for example layers, parts, components and regions, may be shown in excessively large size for better reproducibility and/or for better understanding.

### DETAILED DESCRIPTION OF ILLUSTRATIVE EMBODIMENTS

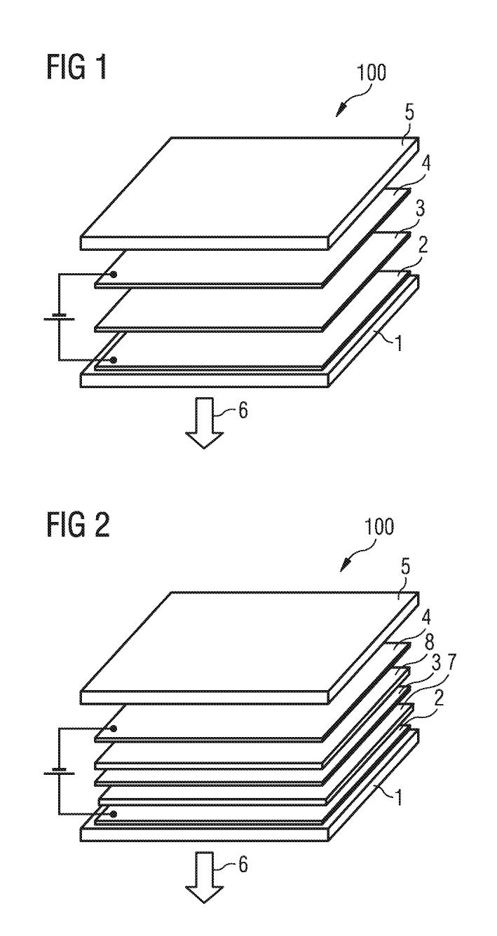

FIG. 1 shows a schematic side view of an optoelectronic component in one embodiment. The organic light-emitting component 100 substrate 1. The substrate 1 may be formed, for example, from glass. A first electrode 2 is arranged directly alongside the substrate 1. The first electrode 2 may be formed, for example, from a transparent conductive material, for example ITO. More particularly, the first electrode 2 has a layer thickness of 100 to 150 nm. The first electrode 2 is followed by an organic light-emitting layer 3. The organic light-emitting layer 3 includes the metal complex as emitter material. The metal complex may be embedded in a matrix material. The embedding can be effected in a homogeneous manner or by means of a concentration gradient. The organic light-emitting layer 3 is followed by a second electrode 4. The second electrode 4 may, for example, be in reflective form. The second electrode 4 may have a layer thickness, for example, of 130 nm. More particularly, only the organic light-emitting layer 3 is arranged between the first electrode 2 and the second electrode 4, and so no further layers are arranged therebetween. In other words, the organic light-emitting component takes the form of an organic light-emitting electrochemical cell (OLEEC). The second electrode 4 may be followed by an encapsulation 5. More particularly, the organic light-emitting component 100 may take the form of a bottom emitter. In other words, the radiation generated in the organic light-emitting layer 3 is emitted in the direction of the first electrode 2 via the first substrate 1 (arrow 6).

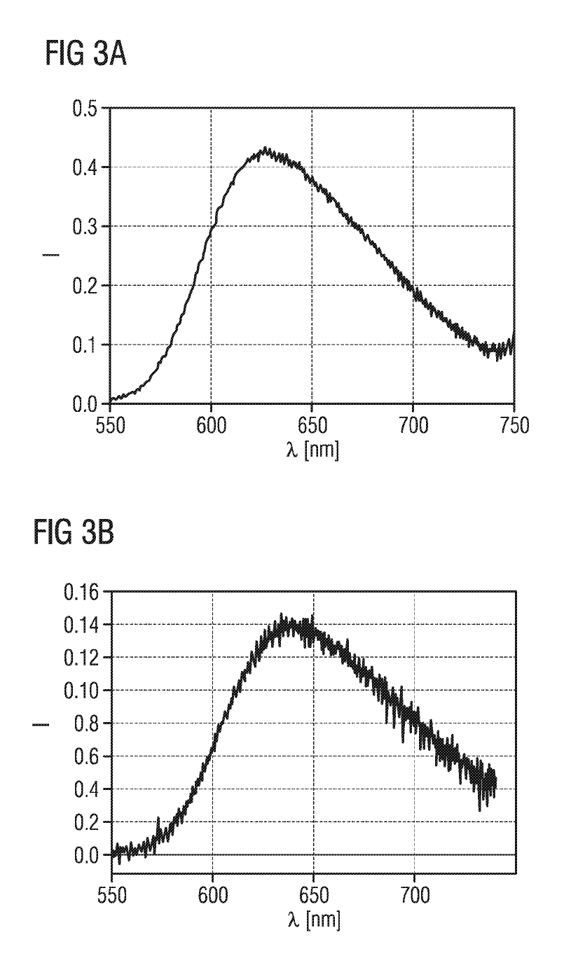

FIG. 2 shows a schematic side view of an organic light-emitting component in one embodiment. The organic light-emitting component 100 of FIG. 2 differs from the organic light-emitting component 100 of FIG. 1 in that it has further layers between the first electrode 2 and the second electrode 4. More particularly, a further layer 7 is arranged between the first electrode 2 and the organic light-emitting layer 3. For example, the further layer 7 may be a hole injection layer. A further layer 8, for example an electron transport layer, may be arranged between the organic light-emitting layer 3 and the second electrode 4. More particularly, the component 100 according to FIG. 2 is an OLED.

Alternatively, the components 100 in FIGS. 1 and 2 may also take the form of top emitters or of transparent components.

FIGS. 3A to 7B show the luminescence properties of two metal complexes:

A: [iridium(2-(4-fluorophenyl)pyridinato)2(2,2′-bipyridine)]PF₆ and

B: [iridium(2-(3-fluorophenyl)pyridinato)2(2,2′-bipyridine)]PF₆.

The metal complexes were each excited in the UV region, especially at 350 nm.

FIG. 3A shows an emission spectrum of working example A as a thin-film sample. The emission spectrum shows the intensity I as a function of the wavelength λ in nm in the form of a graph. The metal complex shows only one wavelength maximum at around 629 nm.

FIG. 3B shows an emission spectrum of working example B as a thin-film sample. The emission spectrum shows the intensity I as a function of the wavelength λ in nm in the form of a graph. The metal complex shows only one wavelength maximum at around 644 nm.

FIG. 4A shows an emission spectrum of working example A as a powder sample. The emission spectrum shows the normalized intensity I_{N} as a function of the wavelength λ in nm in the form of a graph. The metal complex shows a wavelength maximum at around 634 nm and a shoulder at around 521 nm.

FIG. 4B shows an emission spectrum of working example B as a powder sample. The emission spectrum shows the normalized intensity I_{N} as a function of the wavelength λ in nm in the form of a graph. The metal complex shows a wavelength maximum at around 638 nm and a shoulder at around 514 nm.

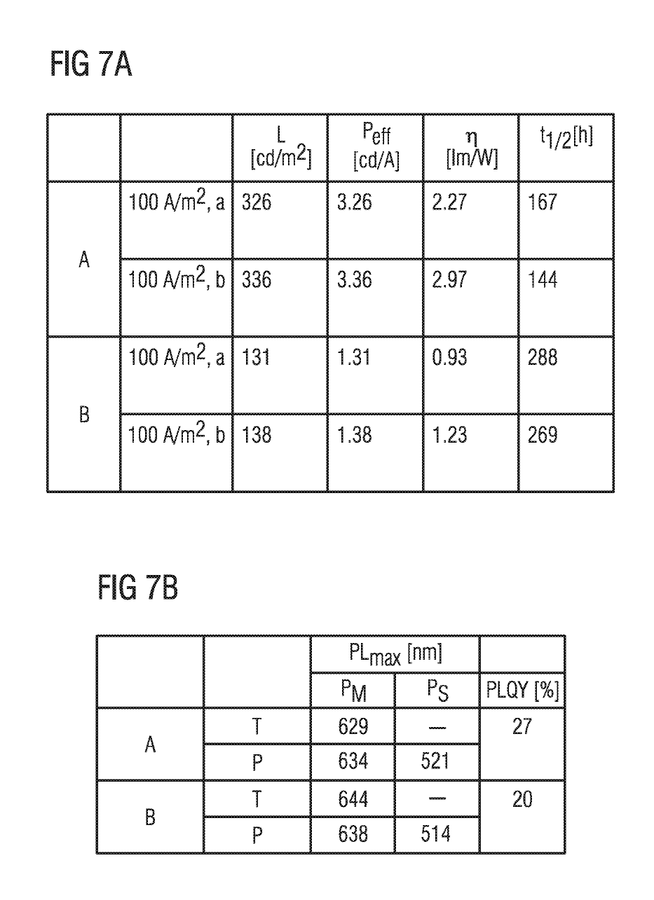

FIG. 7B shows the respective wavelength peak maxima P_{M} and shoulder peak maxima P_{S} of the metal complexes A and B compiled in a table. The samples were analyzed in the form of a thin film (T) and powder (P). The table in FIG. 7B also shows the luminescence quantum yield (PLQY) in %. The metal complexes were excited at 350 nm.

For the metal complex A with PLQY=27%:

T: P_{M}=629 nm and no shoulder peak,

P: P_{M}=634 nm and P_{S}=521 nm.

For the metal complex B with PLQY=20%:

T: P_{M}=644 nm and no shoulder peak,

P: P_{M}=638 nm and P_{S}=514 nm.

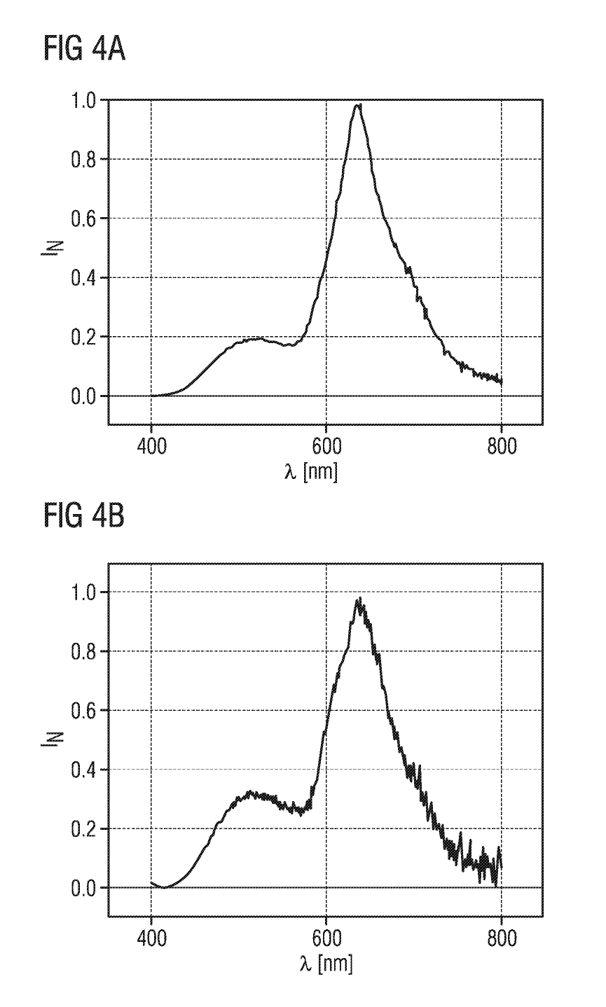

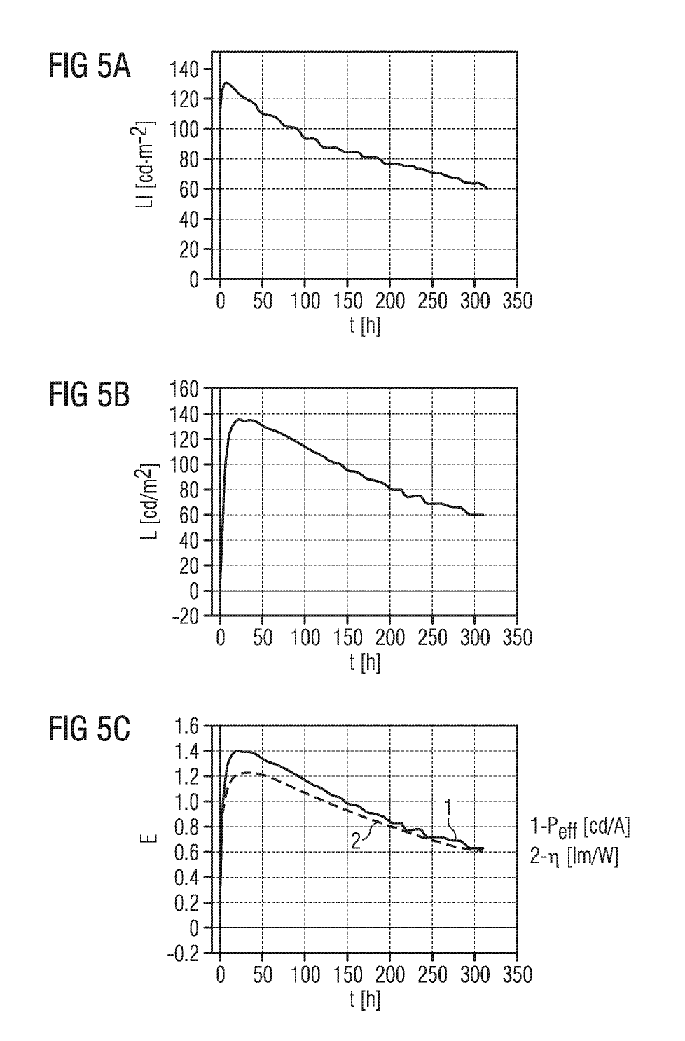

FIGS. 5A and 5B show the luminescence L in cd/m² as a function of the wavelength λ in nm for the metal complex B. FIG. 5A was measured at a duty cycle of 50% and FIG. 5B at a duty cycle of 75%.

FIG. 5C shows the efficiency E, i.e. the power efficiency Peff in candelas per ampere (cd/A) and the light yield η in lumens per watt (lm/W), for the metal complex B. The curves were measured at a duty cycle of 75%. The components were analyzed with a pulsed current at a frequency of 1000 Hz and a current intensity per unit area (in A/m²) of 100.

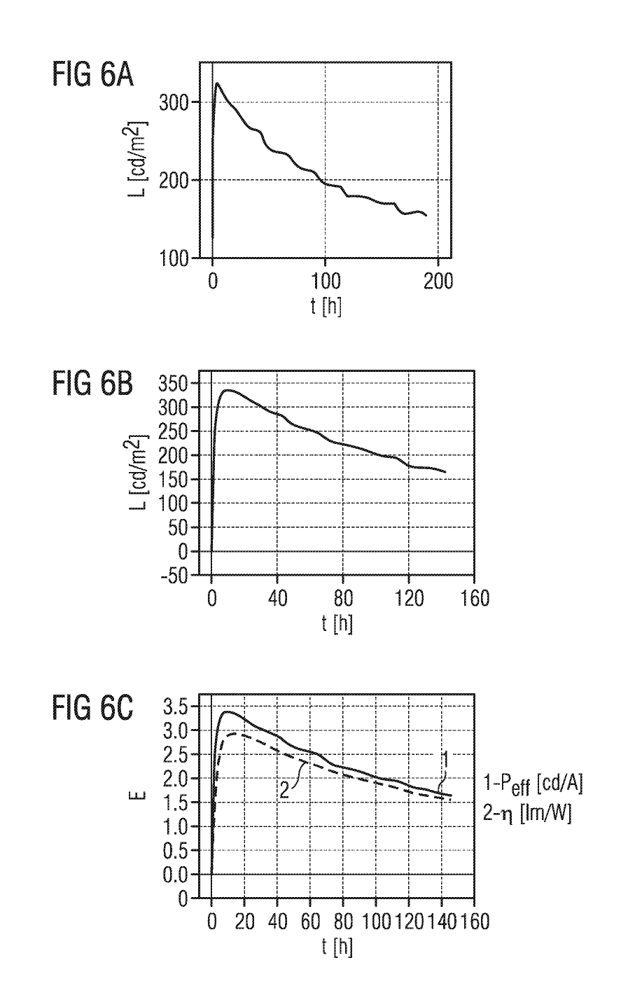

FIGS. 6A and 6B show luminescence L in cd/m² as a function of the wavelength λ in nm for the metal complex A. FIG. 6A was measured at a duty cycle of 50% and FIG. 6B at a duty cycle of 75%.

FIG. 6C shows the efficiency E, i.e. the power efficiency Peff in candelas per ampere (cd/A) and the light yield η in lumens per watt (lm/W), for the metal complex A. The curves were measured at a duty cycle of 75%. The components were analyzed with a pulsed current at a frequency of 1000 Hz and a current intensity per unit area (in A/m²) of 100.

FIG. 7A shows the tabular compilation of the data found in FIGS. 5A to 6C for a component including the respective metal complexes A and B under different conditions, such as the current intensity per unit area (in A/m²) and the duty cycles (a: 50% duty cycle and b: 75% duty cycle). Also shown is the half-life t_{1/2} in hours (h). It is possible to provide red-emitting emitter complexes that exhibit improved component performance (L=3.26 cd/μ² and η=2.97 lm/W), improved stability (t_{1/2}=288 h) and high efficiency.

The working examples described in conjunction with the figures and the features thereof may also be combined with one another in further working examples, even when such combinations are not shown explicitly in the figures. In addition, the working examples described in conjunction with the figures may have additional or alternative features according to the description in the general part.

The invention is not restricted to the working examples by their citation in the description. Instead, the invention encompasses every novel feature and every combination of features, especially including every combination of features in the claims, even when this feature or this combination itself is not specified explicitly in the claims or working examples.

1-17. (canceled)

18. A metal complex having the structural formula I: 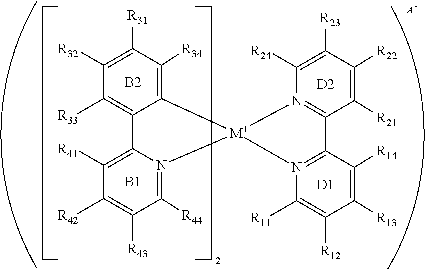
where:
M is a transition metal having an atomic number greater than 40,
a B2 ring is at least one of an aromatic or a heteroaromatic,
a B1 ring, a D1 ring and a D2 ring are each at least one nitrogen-containing ring,
A⁻ is a monovalent anion,
R₁₁, R₁₂, R₁₃, R₁₄, R₂₁, R₂₂, R₂₃, R₂₄, R₃₁, R₃₂, R₃₃, R₃₄, R₄₁, R₄₂, R₄₃, R₄₄ are either each independently selected from the group consisting of —H, —OH, —R₅₀, -phenyl, —OCOR₆₀, —NHCOR₇₀, —OR₈₀, —NR₉₀R₁₀₀, NHR₁₁₀, —C═, —C═C, —C═C—, —C and —NH₂ or each independently selected from the group consisting of —H, —I, —Cl, —Br, —F N⁺R₁₂₀R₁₃₀R₁₄₀, —SO₃R₁₅₀, —CN, —COCl, NO₂, —COOR₁₆₀, —CR₁₇₀R₁₈₀OH, —CR₁₉₀O and —CHO,
wherein R₅₀, R₆₀, R₇₀, R₈₀, R₉₀, R₁₀₀, R₁₁₀ are each independently selected from the group consisting of unbranched saturated hydrocarbon chains having 1 to 20 carbon atoms, branched saturated hydrocarbon chains having 1 to 20 carbon atoms, unbranched unsaturated hydrocarbon chains having 1 to 20 carbon atoms, branched unsaturated hydrocarbon chains having 1 to 20 carbon atoms, aromatic rings and nonaromatic rings,
wherein R₁₂₀, R₁₃₀, R₁₄₀, R₁₅₀, R₁₆₀, R₁₇₀, R₁₈₀, R₁₉₀ are each independently selected from the group consisting of unbranched saturated hydrocarbon chains having 1 to 20 carbon atoms, branched saturated hydrocarbon chains having 1 to 20 carbon atoms and cyclic rings having 3 to 20 carbon atoms, and
wherein at least one of the R₃₁, R₃₂, R₃₃ and R₃₄ radicals is an electron-withdrawing substituent.

19. The metal complex according to claim 18, wherein the electron-withdrawing substituent is selected from the group consisting of —F, —CN, —I, —Cl, —Br and —NO₂.

20. The metal complex according to claim 18, wherein the metal complex is configured to emit radiation from a red spectral range.

21. The metal complex according to claim 18, wherein an emission maximum has a wavelength of 636 +/−8 nm.

22. The metal complex according to claim 18, wherein R₃₁ or R₃₄ is fluorine.

23. The metal complex according claim 22, wherein the D1 ring and/or the D2 ring is a quinoline or isoquinoline.

24. The metal complex according to claim 18, wherein M is selected from the group consisting of Ir, Ru, Os and Pt.

25. The metal complex according to claim 18, wherein the metal complex comprises the following structural formula II: 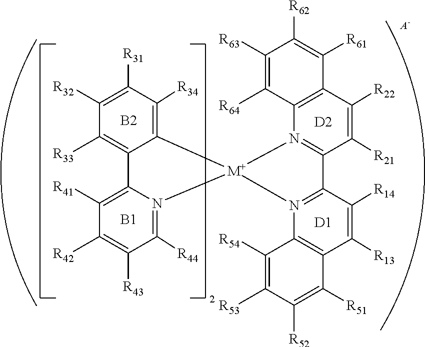
where:
R₃₁ and/or R₃₄ is/are each independently selected from −F, −I, −Br, −Cl, −CN and —NO₂, R₅₁, R₅₂, R₅₃, R₅₄, R₆₁, R₆₂, R₆₃, R₆₄ are each hydrogen, and
M, the B2 ring, the B1 ring, the D1 ring and/or the D2 ring, A⁻, R₄₁, R₄₂, R₄₃, R₄₄, R₃₁, R₃₂, R₃₃, R₃₄, R₁₃, R₁₄, R₂₁, R₂₂ are as defined in claim 1.

26. The metal complex according to claim 25, wherein R₃₁ and/or R₃₄ is/are —F.

27. The metal complex according to claim 25, wherein the B1 ring is part of a substituted or unsubstituted quinolone or of a substituted or unsubstituted isoquinoline.

28. The metal complex according to claim 25, wherein the B2 ring is a fluorine-substituted phenyl radical.

29. An organic light-emitting component comprising:
at least one organic light-emitting layer between two electrodes,
wherein the organic light-emitting layer comprises the metal complex according to claim 18 as emitter material.

30. The organic light-emitting component according to claim 29, wherein the organic light-emitting component is an organic light-emitting diode.

31. The organic light-emitting component according to claim 29, wherein the organic light-emitting component is an organic light-emitting electrochemical cell.

32. The organic light-emitting component according to claim 29, wherein the organic light-emitting layer is produced from a liquid phase, and wherein the metal complex is homogeneously distributed in a matrix material.

33. The organic light-emitting component according to claim 29, wherein the organic light-emitting component is configured to emit radiation from a red spectral region.

34. A metal complex having an emission maximum at a wavelength of 636+/−8 nm and the structural formula I: 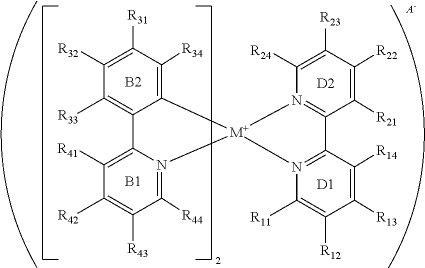
where:
M is a transition metal having an atomic number greater than 40,
a B2 ring is at least one of an aromatic or a heteroaromatic,
a B1 ring, a D1 ring and a D2 ring are each at least one nitrogen-containing ring,
A⁻ is a monovalent anion,
R₁₁, R₁₂, R₁₃, R₁₄, R₂₁, R₂₂, R₂₃, R₂₄, R₃₁, R₃₂, R₃₃, R₃₄, R₄₁, R₄₂, R₄₃, R₄₄ are either each independently selected from the group consisting of —H, —OH, —R₅₀, -phenyl, —OCOR₆₀, —NHCOR₇₀, —OR₈₀, —NR₉₀R₁₀₀, —NHR₁₁₀, —C═, —C═C, —C═C—, —C and —NH₂ or each independently selected from the group consisting of —H, —I, —Cl, —Br, —F, N⁺R₁₂₀R₁₃₀R₁₄₀, —SO₃R₁₅₀, —CN, —COCl, —NO₂, —COOR₁₆₀, —CR₁₇₀R₁₈₀OH, —CR₁₉₀O and —CHO,
wherein R₅₀, R₆₀, R₇₀, R₈₀, R₉₀, R₁₀₀, R₁₁₀ are each independently selected from the group consisting of unbranched saturated hydrocarbon chains having 1 to 20 carbon atoms, branched saturated hydrocarbon chains having 1 to 20 carbon atoms, unbranched unsaturated hydrocarbon chains having 1 to 20 carbon atoms, branched unsaturated hydrocarbon chains having 1 to 20 carbon atoms, aromatic rings and nonaromatic rings,
wherein R₁₂₀, R₁₃₀, R₁₄₀, R₁₅₀, R₁₆₀, R₁₇₀, R₁₈₀, R₁₉₀ are each independently selected from the group consisting of unbranched saturated hydrocarbon chains having 1 to 20 carbon atoms, branched saturated hydrocarbon chains having 1 to 20 carbon atoms and cyclic rings having 3 to 20 carbon atoms,
wherein at least R₃₄ radicals is an electron-withdrawing substituent, and wherein the electron-withdrawing substituent is selected from the group consisting of —F, —CN, —I, —Cl, —Br and —NO₂.
